(19) United States
(12) Patent Application Publication
(10) Pub. No.: US 2009/0265592 A1
(43) Pub. Date: Oct. 22, 2009

(54) MEMORY DEVICE AND TEST METHOD THEREOF

(76) Inventors: Hsiang-Huang Wu, Taipei City (TW); Jih-Nung Lee, Taipei City (TW)

Correspondence Address: LADAS & PARRY LLP, 224 SOUTH MICHIGAN AVENUE, SUITE 1600, CHICAGO, IL, 60604, US

(21) Appl. No.: 12/423,343

(22) Filed: Apr. 14, 2009

(30) Foreign Application Priority Data
Apr. 18, 2008 (TW) 097114220

(51) Int. Cl. G11C 29/10; G06F 11/263

(52) U.S. Cl. 714/718; 714/E11.177

(57) ABSTRACT

The present invention provides a memory device and a test method thereof that can detect a coupling fault between two memory arrays. The memory device includes a memory array unit and a test module. The memory array unit includes a value memory array and a mask memory array. The test module is coupled to the memory array unit for generating a test pattern signal that is based on a test rule and that is provided to the memory array unit for performing testing on the memory array unit. The test rule includes a number (M) of first test segments for testing the value memory array and a number (N) of second test segments for testing the mask memory array. The first test segments and the second test segments are interleaved in the test rule.

### CROSS-REFERENCE TO RELATED APPLICATION

This application claims priority of Taiwanese application no. 097114220, filed on Apr. 18, 2008.

### BACKGROUND OF THE INVENTION

1. Field of the Invention

This invention relates to a memory device and a test method thereof, more particularly to a memory device and test method thereof capable of detecting a coupling fault between a value memory array and a mask memory array of a ternary content-addressable memory.

2. Description of the Related Art

A ternary content-addressable memory (TCAM) includes a value memory array and a mask memory array. The value memory array is for storing a plurality of value bits, and the mask memory array is for storing a plurality of mask bits for masking the value memory array. In operation, the value bit and the mask bit cooperate to indicate one of three possible states: “0”, “1”, and “don't care”.

In a conventional test method for testing the ternary content-addressable memory in order to determine whether the ternary content-addressable memory is faulty, testing is first performed on the value memory array, and after completing testing of the value memory array, testing is then performed on the mask memory array.

Since the conventional test method tests the value memory array and the mask memory array separately, the conventional test method lacks the ability to detect a coupling fault resulting from an interaction between the value memory array and the mask memory array of the ternary content-addressable memory.

### SUMMARY OF THE INVENTION

Therefore, an object of the present invention is to provide a memory device that is capable of detecting a coupling fault between two memory arrays.

According to one aspect of the present invention, there is provided a memory device comprising a memory array unit and a test module.

The memory array unit includes a value memory array for storing a value bit, and a mask memory array coupled to the value memory array for storing a mask bit for masking the value memory array. The test module is coupled to the memory array unit for generating a test pattern signal that is based on a test rule and that is provided to the memory array unit for performing testing on the memory array unit.

The test rule includes a number (M) of first test segments for testing the value memory array and a number (N) of second test segments for testing the mask memory array. The first test segments and the second test segments are interleaved in the test rule. M and N are integers not smaller than 2.

Another object of the present invention is to provide a test method capable of detecting a coupling fault between two memory arrays.

According to another aspect of the present invention, there is provided a test method for testing a memory array unit. The memory array unit includes a value memory array and a mask memory array. The test method comprises the steps of:

generating a test pattern signal that is based on a test rule and that is provided to the memory array unit for performing testing on the memory array unit; and

based on an output value from the memory array unit, generating a test result;

wherein, the test rule includes a number (M) of first test segments for testing the value memory array, and a number (N) of second test segments for testing the mask memory array, the first test segments and the second test segments are interleaved in the test rule, and M and N are integers not smaller than 2.

### BRIEF DESCRIPTION OF THE DRAWINGS

Other features and advantages of the present invention will become apparent in the following detailed description of the preferred embodiment with reference to the accompanying drawings, of which:

FIG. 1 is a schematic block diagram to illustrate a preferred embodiment of a memory device according to the present invention; and

FIG. 2 illustrates an exemplary test rule used in the preferred embodiment.

### DETAILED DESCRIPTION OF THE PREFERRED EMBODIMENT

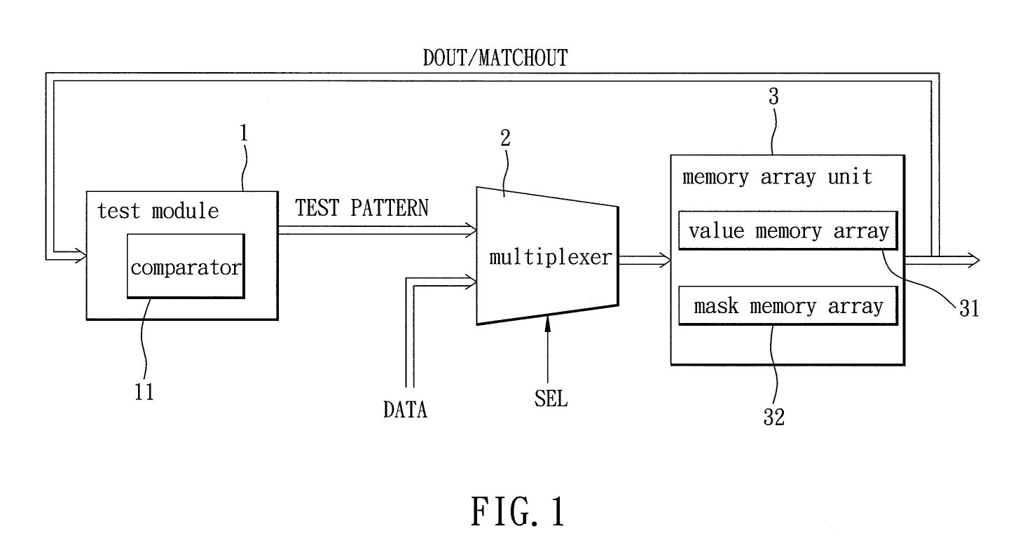

FIG. 1 illustrates a preferred embodiment of a memory device according to the present invention. The memory device comprises a memory array unit 3, a multiplexer 2, and a test module 1.

In this embodiment, the memory array unit 3 is a ternary content-addressable memory (TCAM) that includes a value memory array 31 and a mask memory array 32. The value memory array 31 is for storing at least one value bit, and the mask memory array 32 is for storing at least one mask bit for masking the value memory array 31.

The multiplexer 2 is for permitting output of one of a test pattern signal (TEST PATTERN) and a data signal (DATA) to the memory array unit 3 in accordance with a selection control signal (SEL). In use, when the memory device operates in a normal mode, the multiplexer 2 permits output of the data signal (DATA). If, in accordance with this embodiment, the memory device is used in a network router, the data signal (DATA) can be a network data signal, such as an IP address. On the other hand, when the memory device operates in a test mode for performing testing on the memory array unit 3, the multiplexer 2 permits output of the test pattern signal (TEST PATTERN).

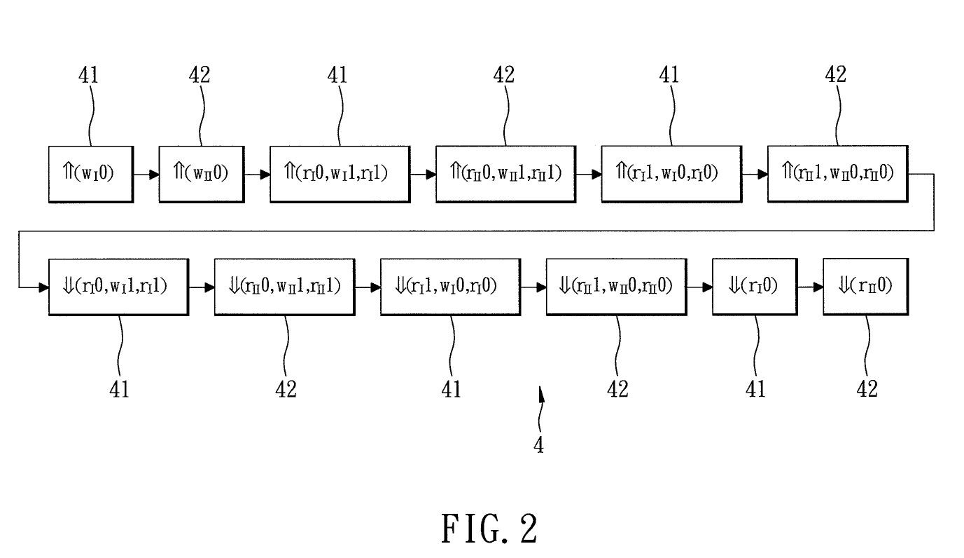

The test module 1 is coupled to the multiplexer 2 and the memory array unit 3, and generates the test pattern signal (TEST PATTERN) that is based on a test rule 4 (see FIG. 2) and that is provided to the memory array unit 3 through the multiplexer 2 for performing testing on the memory array unit 3. Referring to FIG. 2, the test rule 4 includes a number (M) of first test segments 41 for testing the value memory array 31 and a number (N) of second test segments 42 for testing the mask memory array 32, wherein M and N are integers not smaller than 2. Each test segment 41, 42 can include an address direction, a read operation, and/or a write operation, depending on test requirements. It is noted that the first test segments 41 and the second test segments 42 are interleaved in the test rule 4, so that when testing is performed on the memory array unit 3, the value memory array 31 and the mask memory array 32 are alternately tested.

In this embodiment, the first test segments 41 and the second test segments 42 of the test rule 4 utilize a test algorithm, more particularly, a March C+ test algorithm. The March C+ test algorithm includes the following six test elements:

test element (1): [symbol] (w0);

test element (2): [symbol] (r0,w1,r1);

test element (3): [symbol] (r1,w0,r0);

test element (4): [symbol] (r0,w1,r1);

test element (5): [symbol] (r1,w0,r0); and

test element (6): [symbol] (r0);

wherein, [symbol] denotes an ascending progression from address 0 to address n−1, [symbol] denotes a descending progression from address n−1 to address 0, w0 denotes an operation in which a bit value of 0 is written, w1 denotes an operation in which a bit value of 1 is written, r0 denotes a read operation in which an expected bit value is 0, and r1 denotes a read operation in which an expected bit value is 1.

The test rule 4 therefore includes six of the first test segments 41 interleaved with six of the second test segments 42 as follows:

first test segment 41 (1): [symbol] (w_{I}0);

second test segment 42 (1): [symbol] (w_{II}0)

first test segment 41 (2): [symbol] (r_{I}0,w_{I}1,r_{I}1)

second test segment 42 (2): [symbol] (r_{II}0,w_{II}1,r_{II}1)

first test segment 41 (3): [symbol] (r_{I}1,w_{I}0,r_{I}0);

second test segment 42 (3): [symbol] (r_{II}1,w_{II}0,r_{II}0);

first test segment 41 (4): [symbol] (r_{I}0,w_{I}1,r_{I}1);

second test segment 42 (4): [symbol] (r_{II}0,w_{II}1,r_{II}1);

first test segment 41 (5): [symbol] (r_{I}1, w_{I}0, r_{I}0);

second test segment 42 (5): [symbol] (r_{II}1,w_{II}0,r_{II}0);

first test segment 41 (6): [symbol] (r_{I}0); and

second test segment 42 (6): [symbol] (r_{II}0);

wherein, I indicates an operation performed on the value memory array 31, and II indicates an operation performed on the mask memory array 32.

The preferred embodiment of the memory device is thus not only capable of providing inherent error detection capabilities of the test algorithm, but owing to the interleaving of the first test segments 41 and the second test segments 42 in the test rule 4, is also capable of detecting a coupling fault between the two memory arrays 31, 32, thereby overcoming the drawback of the prior art.

In addition, the memory device can determine whether the memory array unit 3 is faulty based on an output value detected from the memory array unit 3, such as an output value of a match signal (MATCHOUT) or a data signal (DOUT) as shown in FIG. 1. For instance, the test module 1 can generate the test pattern signal (TEST PATTERN) for the read operation that is then provided to the memory array unit 3, and subsequently read out the output value from the output (such as the data signal (DOUT)) of the memory array unit 3. Using a comparator 11 included in the test module 1, the output value read out can then be compared to a predetermined value for determining in accordance with a comparison result whether the memory array unit 3 is faulty. If the output value read out matches the predetermined value, a test result is generated indicating that the memory array unit 3 is not faulty. If the output value read out does not match the predetermined value, the test result is generated indicating that the memory array unit 3 is faulty. In this embodiment, utilization of the output value of the memory array unit 3 when performing testing on the memory array unit 3 increases the efficacy of the testing performed.

It is noted that, in this invention, the test algorithm can be one other than the March C+test algorithm, and the memory array unit 3 can be one other than the ternary content-addressable memory, and are not limited to what has been described herein.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

What is claimed is:

1. A memory device comprising:
a memory array unit including a value memory array for storing a value bit, and a mask memory array coupled to said value memory array for storing a mask bit for masking said value memory array; and
a test module coupled to said memory array unit for generating a test pattern signal that is based on a test rule and that is provided to said memory array unit for performing testing on said memory array unit;
wherein said test rule includes a number (M) of first test segments for testing said value memory array and a number (N) of second test segments for testing said mask memory array, said first test segments and said second test segments are interleaved in said test rule, and M and N are integers not smaller than 2.

2. The memory device as claimed in claim 1, wherein said test module includes:
a comparator for comparing a predetermined value and an output value, and for determining in accordance with a comparison result whether said memory array unit is faulty;
wherein said output value is one that is output from said memory array unit.

3. The memory device as claimed in claim 1, wherein said memory array unit is a ternary content-addressable memory (TCAM).

4. The memory device as claimed in claim 1, wherein said first test segments and said second test segments utilize a test algorithm, and said test algorithm is a March test algorithm.

5. The memory device as claimed in claim 1, wherein said first test segments and said second test segments utilize a test algorithm, and said test algorithm is a March C+ test algorithm.

6. The memory device as claimed in claim 1, wherein each of said first test segments and each of said second test segments includes at least one of an address direction, a read operation and a write operation.

7. The memory device as claimed in claim 1, wherein said memory device is adapted for use in a network router.

8. A test method for testing a memory array unit, the memory array unit including a value memory array and a mask memory array, said test method comprising the steps of:
generating a test pattern signal that is based on a test rule and that is provided to the memory array unit for performing testing on the memory array unit; and
based on an output value from the memory array unit, generating a test result;
wherein, the test rule includes a number (M) of first test segments for testing the value memory array, and a number (N) of second test segments for testing the mask memory array, the first test segments and the second test segments are interleaved in the test rule, and M and N are integers not smaller than 2.

9. The test method as claimed in claim 8, wherein the step of generating a test result based on an output value from the memory array unit includes the sub-steps of:
comparing the output value from the memory array unit and a predetermined value, and determining in accordance with a comparison result whether the memory array unit is faulty.

10. The test method as claimed in claim 8, wherein the memory array unit is a ternary content-addressable memory (TCAM).

11. The test method as claimed in claim 8, wherein the first test segments and the second test segments utilize a test algorithm, and the test algorithm is a March test algorithm.

12. The test method as claimed in claim 8, wherein the first test segments and the second test segments utilize a test algorithm, and the test algorithm is a March C+ test algorithm.

13. The test method as claimed in claim 8, wherein each of the first test segments and each of the second test segments includes at least one of an address direction, a read operation and a write operation.

14. The test method as claimed in claim 8, wherein said test method is performed on a network router.
